(19) United States
(12) Patent Application Publication
(10) Pub. No.: US 2017/0163226 A1
(43) Pub. Date: Jun. 8, 2017

(54) FAST SWITCHING POWER AMPLIFIER, LOW NOISE AMPLIFIER, AND RADIO FREQUENCY SWITCH CIRCUITS

(71) Applicant: SKYWORKS SOLUTIONS, INC., Woburn, MA (US)

(72) Inventors: OLEKSANDR GORBACHOV, IRVINE, CA (US); LOTHAR MUSIOL, IRVINE, CA (US); LISETTE L. ZHANG, IRVINE, CA (US)

(21) Appl. No.: 15/358,509

(22) Filed: Nov. 22, 2016

Related U.S. Application Data
(60) Provisional application No. 62/264,473, filed on Dec. 8, 2015.

(51) Int. Cl. H03F 3/24; H04B 1/3827; H03F 3/195

(52) U.S. Cl. CPC H03F 3/245; H03F 3/195; H04B 1/3827; H03F 2200/451; H03F 2200/294

(57) ABSTRACT

A speed-up circuit connectable to a capacitive load to reduce charging time thereof from a pulsed current source connected there includes a first circuit node connectable to the capacitive load. An operational amplifier circuit is connected to the first circuit node and configured as a low resistance voltage source. Added current from the operational amplifier flows to the capacitive load for a predetermined duration between the pulsed current source transitioning between a deactivated state and an activated state, and in response to an activation of the pulsed current source. The added current is combined with the current from the pulsed current source to reduce switching time of the load.

### CROSS-REFERENCE TO RELATED APPLICATIONS

The application relates to and claims the benefit under 35 U.S.C. §119(e) to U.S. Provisional Patent Application No. 62/264,473 filed Dec. 8, 2015 and entitled “CIRCUIT FOR FAST SWITCHING PA, LNA AND RF SWITCH,” the entire contents of which is wholly incorporated by reference herein.

### STATEMENT RE: FEDERALLY SPONSORED RESEARCH/DEVELOPMENT

Not Applicable

### BACKGROUND

1. Technical Field

The present disclosure relates generally to radio frequency (RF) circuits, and more particularly, to fast switching power amplifiers, low noise amplifiers, and RF switches.

2. Related Art

Complex, multi-function electronic devices are comprised of many interconnected modules and components, each of which serves a dedicated purpose. As a general example, wireless communication devices may be comprised of a transmit chain and a receive chain, with the antenna and the transceiver circuit being a part of both the transmit chain and receive chain. The transmit chain may additionally include a power amplifier for increasing the output power of the generated radio frequency signal from the transceiver, while the receive chain may include a low noise amplifier for boosting the weak received signal so that information can be accurately and reliably extracted therefrom.

The low noise amplifier and the power amplifier may together comprise a front end module or front end circuit, which also includes an radio frequency switch circuit that selectively interconnects the power amplifier and the low noise amplifier to the antenna. The connection to the antenna is switched between the receive chain circuitry, i.e., the low noise amplifier and the receiver, and the transmit chain circuitry, i.e., the power amplifier and the transmitter. In time domain duplex communications systems where a single antenna is used for both transmission and reception, this switching between the receive chain and the transmit chain occurs rapidly many times throughout a typical communications session. Besides radio frequency communications systems, switches and switch circuits find application in many other contexts.

The radio frequency switches and the amplifier circuits of the front end module are manufactured as an integrated circuit. Although the gallium arsenide (GaAs) or silicon-on-insulator (SOI) fabrication technologies were favored devices for high-power applications such as cellular communications systems and wireless local area network client interface devices, complementary metal oxide semiconductor (CMOS) fabrication is becoming increasingly mainstream for its lower manufacturing costs.

It is common for the power amplifier circuits and the low noise amplifier circuits to be controlled with current mirror circuits, which typically include a pair of transistors coupled together such that the current through one of the devices matches, or mirrors the current in the other device. The mirror transistor is connected to the gate of the radio frequency amplifier transistor over a mirror resistor, while the mirror transistor is connected to a control circuit that turns on and turns off the mirror transistor within a specific timeframe. The current sources typically include high ohmic circuitry, which are understood to have residual capacitances. For instance, there is the mirror transistor gate capacitance, as well as the coupled capacitor that carries the radio frequency signal to the radio frequency amplifier transistor gate. Such residual capacitances are understood to introduce significant time delays in transient responses, which is particularly problematic with pulsed signals utilized in digital circuitry as well as high frequency RF signals. Increased current at the beginning of the pulsed signals is usually insufficient for reducing load charging time and discharging time.

Accordingly, there is a need in the art for speed-up circuits that are utilized with current mirrors that bias amplifier circuits, particularly those for radio frequency amplification applications such as power amplifiers and low noise amplifiers. There is a need for such speed-up circuits to reduce charging and discharging time of the current mirror circuits, so that the main amplifier transistor reaches normal bias conditions faster.

### BRIEF SUMMARY

A speed-up circuit connectable to a capacitive load to reduce charging time thereof from a pulsed current source connected thereto is disclosed. The circuit may include a first circuit node connectable to the capacitive load. Additionally, the circuit may include an operational amplifier circuit connected to the first circuit node and configured as a low resistance voltage source. Added current from the operational amplifier may flow to the capacitive load through the first circuit node for a predetermined duration between the pulsed current source transitioning between a deactivated state and an activated state, and in response to an activation of the pulsed current source. The added current may be combined with the current from the pulsed current source.

According to another embodiment, there is an amplifier circuit a primary amplification stage, and a current mirror connected to the primary amplification stage. The current mirror may be driven by a pulsed current source. Additionally, the amplifier circuit may include a speed-up circuit that is connected to the current mirror. Added current from the speed-up circuit may flow to the current mirror for a predetermined duration between the pulsed current source transitioning between a deactivated state and an activated state, and in response to an activation of the pulsed current source. The added current may be combined with the current from the pulsed current source to reduce switching time of the current mirror.

Yet another embodiment of the present disclosure is directed to a different amplifier circuit. The circuit may include a primary amplification stage, and a current mirror connected to the primary amplification stage. The current mirror may be driven by a pulsed current source. The amplifier circuit may also include a speed-up circuit that is connected to the primary amplification stage. Added current from the speed-up circuit may flow to the primary amplification stage for a predetermined duration between the pulsed current source transitioning between a deactivated state and an activated state and in response to an activation of the pulsed current source. The added current may be combined with the current from the pulsed current source to reduce switching time of the primary amplification stage.

The present disclosure also contemplates a radio frequency communications module with the aforementioned amplifier circuit, as well as a wireless communications device that incorporates such a radio frequency communications module. The present disclosure will be best understood by reference to the following detailed description when read in conjunction with the accompanying drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a block diagram of a speed-up circuit in accordance with various embodiments of the present disclosure in an exemplary circuit with a capacitive load driven by a current source;

FIG. 2 is a schematic diagram of the speed up circuit;

FIG. 3 is a Smith chart plotting the input reflection coefficient of the speed-up circuit shown in FIG. 2;

FIG. 4 is a schematic diagram of the speed-up circuit shown connected to the capacitive load and a pulsed current source;

FIG. 5A is a graph plotting the simulated current responses over time at particular segments of the circuit as shown in FIG. 4;

FIG. 5B is a graph magnifying details of the simulated current responses plotted in FIG. 5A;

FIG. 6A is a graph plotting the simulated voltage responses over time at particular segments of the circuit as shown in FIG. 4;

FIG. 6B is a graph magnifying details of the simulated voltage responses plotted in FIG. 6A;

FIG. 7 is a block diagram of a first embodiment of an amplifier circuit biased with a current mirror circuit and including the speed-up circuit;

FIG. 8 is a schematic diagram of the first embodiment of the amplifier circuit generally shown in FIG. 7;

FIG. 9 is a graph plotting the simulated current responses over time at particular segments of the amplifier circuit shown in FIG. 8 with a resistor connecting the speed-up circuit to the load having a value set to 10 kΩ;

FIG. 10 is a graph plotting the simulated current responses over time at particular segments of the amplifier circuit shown in FIG. 8 with the resistor connecting the speed-up circuit to the load having a value set to 1Ω;

FIG. 11 is a graph plotting the voltage responses over time at particular segments of the amplifier circuit shown in FIG. 8 with the resistor connecting the speed-up circuit to the load having a value set to 10 kΩ;

FIG. 12 is a graph plotting the voltage responses over time at particular segments of the amplifier circuit shown in FIG. 8 with the resistor connecting the speed-up circuit to the load having a value set to 1Ω;

FIG. 13 is a block diagram of a second embodiment of the amplifier circuit biased with the current mirror circuit and including the speed-up circuit;

FIG. 14 is a schematic diagram of the second embodiment of the amplifier circuit generally shown in FIG. 13;

FIG. 15 is a graph plotting the simulated current responses over time at particular segments of the amplifier circuit shown in FIG. 14 with the resistor connecting the speed-up circuit to the load having a value set to 10 kΩ;

FIG. 16 is a graph plotting the simulated current responses over time at particular segments of the amplifier circuit shown in FIG. 14 with the resistor connecting the speed-up circuit to the load having a value set to 1Ω;

FIG. 17 is a graph plotting the voltage responses over time at particular segments of the amplifier circuit shown in FIG. 14 with the resistor connecting the speed-up circuit to the load having a value set to 10 kΩ;

FIG. 18 is a graph plotting the voltage responses over time at particular segments of the amplifier circuit shown in FIG. 14 with the resistor connecting the speed-up circuit to the load having a value set to 1Ω;

FIG. 19 is a schematic diagram of the third embodiment of the amplifier circuit generally shown in FIG. 13;

FIG. 20 is a graph plotting the simulated current responses over time at particular segments of the amplifier circuit shown in FIG. 19;

FIG. 21 is a graph plotting the voltage responses over time at particular segments of the amplifier circuit shown in FIG. 19;

FIG. 22 a block diagram of an exemplary wireless communications device that may incorporate an amplifier circuit in accordance with the present disclosure;

FIG. 23 is a schematic diagram of a packaged amplifier module; and

FIG. 24 is a schematic diagram of a cross-section of the packaged amplifier module shown in FIG. 23.

### DETAILED DESCRIPTION

The detailed description set forth below in connection with the appended drawings is intended as a description of the several presently contemplated embodiments of speed-up circuits and amplifier circuits incorporating the same, and are not intended to represent the only form in which the disclosed circuits may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

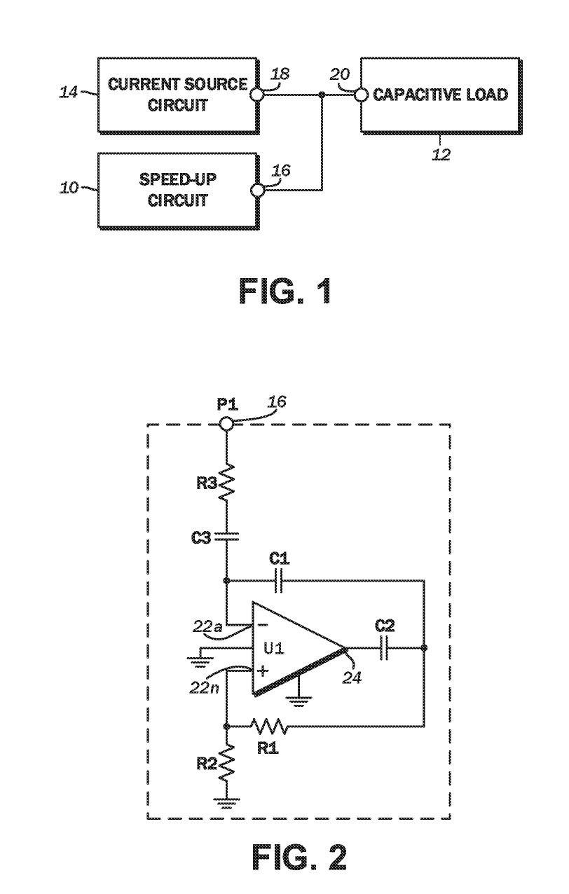

Referring to the block diagram of FIG. 1, the present disclosure contemplates a speed-up circuit 10 that is connected to a capacitive load 12 that is being driven by a pulsed current generated by a current source circuit 14. As will be described in further detail below, the capacitive load may be a radio frequency amplifier such as a power amplifier for transmit RF signals or a low noise amplifier for receive RF signals. It is also contemplated, however, that the capacitive load may be any digital logic circuit. The pulsed current is understood to have a deactivated state and an activated state, and is characterized by a transition period between the two that occurs over a certain duration.

The speed-up circuit 10 may operate as a low resistance voltage source that adds current during this transition, and effectively functions as a negative capacitor. The speed-up circuit 10 has an output 16, and the current source circuit 14 likewise has an output 18. The capacitive load 12 has an input 20. The output 16 of the speed-up circuit 10 is connected to the input 20 of the capacitive load 12, as is the output 18 of the current source circuit 14.

The schematic diagram of FIG. 2 illustrates additional details of the speed-up circuit 10 in accordance with various embodiments of the present disclosure. Again, the speed-up circuit 10 includes the output 16, which is shown as port P1. There is an operational amplifier U1 having an inverting input 22a, and a non-inverting input 22b, as well as a single-ended output 24. The inverting input 22a is connected to a capacitor C3 and a capacitor C1. The capacitor C3 is also connected to the port P1 via a resistor R3. The non-inverting input 22b is connected to a resistor R1 and to a resistor R2 that is connected to ground. The single-ended output 24 is connected to a capacitor C2, with the first capacitor C1 and the first resistor R1 being connected thereto.

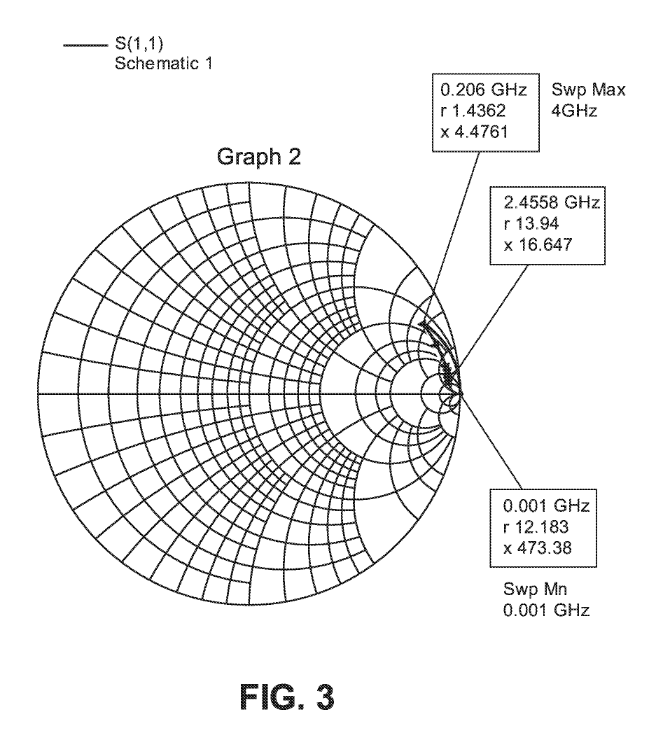

As shown in the Smith chart of FIG. 3, which plots the input reflection coefficient S11 of the speed-up circuit 10, a negative capacitance is exhibited at low frequencies. In the illustrated example, low frequency is understood to refer to frequencies up to 206 Mhz. Furthermore, the speed-up circuit 10 has a high impedance over a wide frequency range. As will be recognized by those having ordinary skill in the art, the capacitance values of the capacitor C1, C2, and C3, and the resistance values of resistor R1 and R2, together with the gain, bandwidth, and output impedance of the operational amplifier U1 may be tuned to achieve the desirable performance with specific S-parameter characteristics.

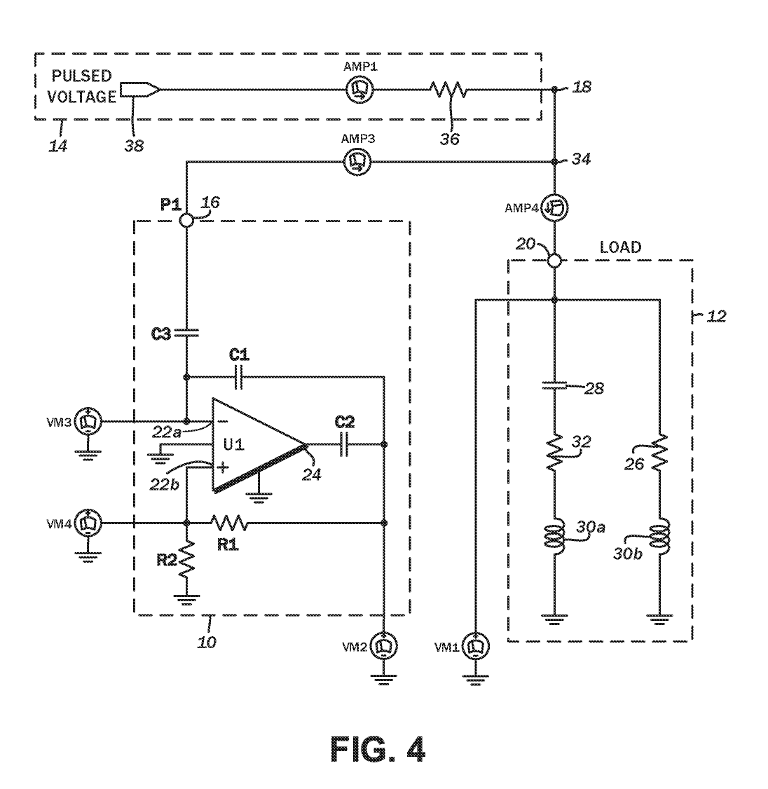

The various embodiments of the present disclosure contemplate the use of the speed-up circuit 10 to reduce the switching time in capacitive loads, including radio frequency amplifiers such as power amplifiers and low noise amplifiers. Referring to the schematic diagram of FIG. 4, the same speed-up circuit 10 described above is connected to the capacitive load 12, which is represented with a resistor 26 and a capacitor 28. Inductors 30a and inductors 30b having simulated values of 0.5 nH, are understood to correspond to the bond wires that connect the capacitive load 12 to ground, together with an associated resistive loss 32. By way of example, and for purposes of simulating the performance of the speed-up circuit 10, the capacitor 28 has a simulated value of 2 pF, while the resistor 26 has a simulated value of 1 MΩ. The speed-up circuit 10 is connected to the capacitive load 12 at a junction 34. Additionally connected to the junction 34 is the output 18 of the current source circuit 14, which is generally represented as a large resistor 36 with an exemplary value of 10 kΩ, and a pulsed voltage source 38.

The speed-up circuit 10 may also be referred to as an operational amplifier circuit, as the primary component is the operational amplifier U1. With respect to the various passive components connected to the operational amplifier U1, the resistor R1 has a simulated value of 1.5 kΩ, the resistor R2 has a simulated value of 10 kΩ, and the capacitors C1, C2, and C3 each have a simulated value of 10 pF.

When the operational amplifier U1 is enabled but the current source circuit 14 is not generating the aforementioned pulsed current, there is no current flowing to the capacitive load 12. However, once the pulsed current is flowing to the capacitive load 12, the current generated by the operational amplifier U1 is added thereto and also flows to the capacitive load 12. The pulsed current is understood to have an activated state and a deactivated state, and the added current from the speed-up circuit 10 is generated and flowing to the capacitive load 12 during the transition from the deactivated state to the activated state. In other words, the added current from the speed-up circuit 10 is generated in response to the pulsed current. The speed-up circuit 10 is understood to define its own resistor-capacitor (RC) time constant, and the current flow increase from the speed-up circuit corresponds thereto. In accordance with various embodiments, the resistance value between the speed-up circuit 10 and the capacitive load 12 may be substantially lower than the resistor 36 of the current source circuit 14, so that the charging time constant can be substantially reduced.

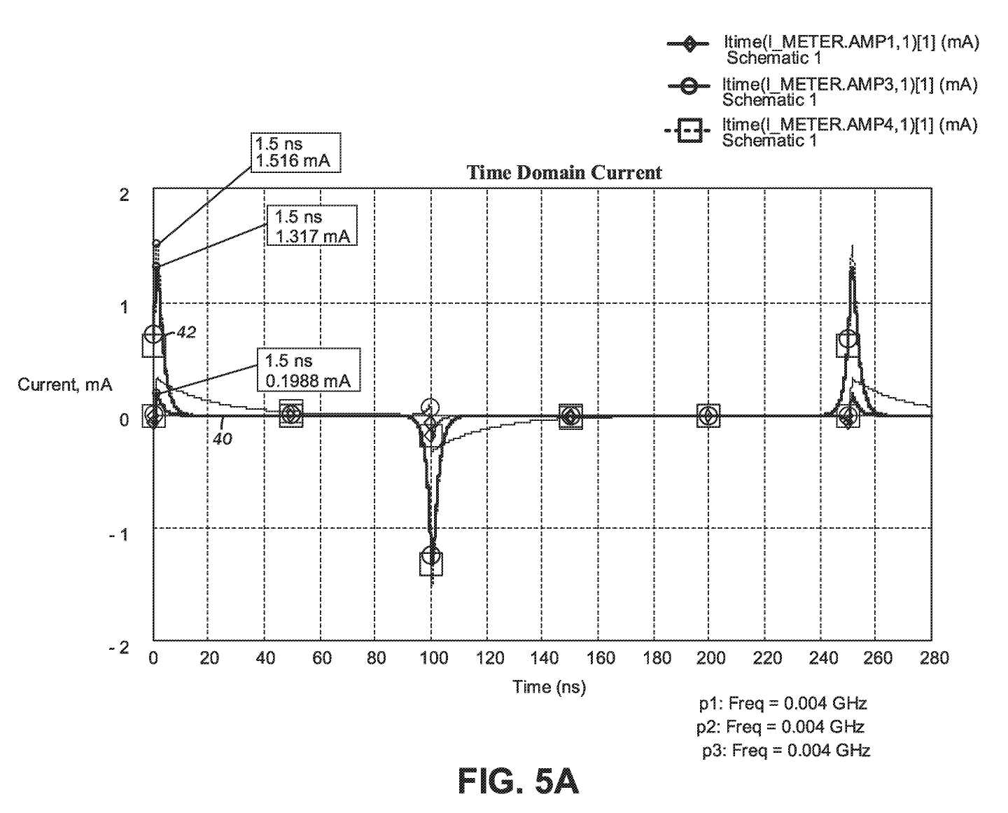

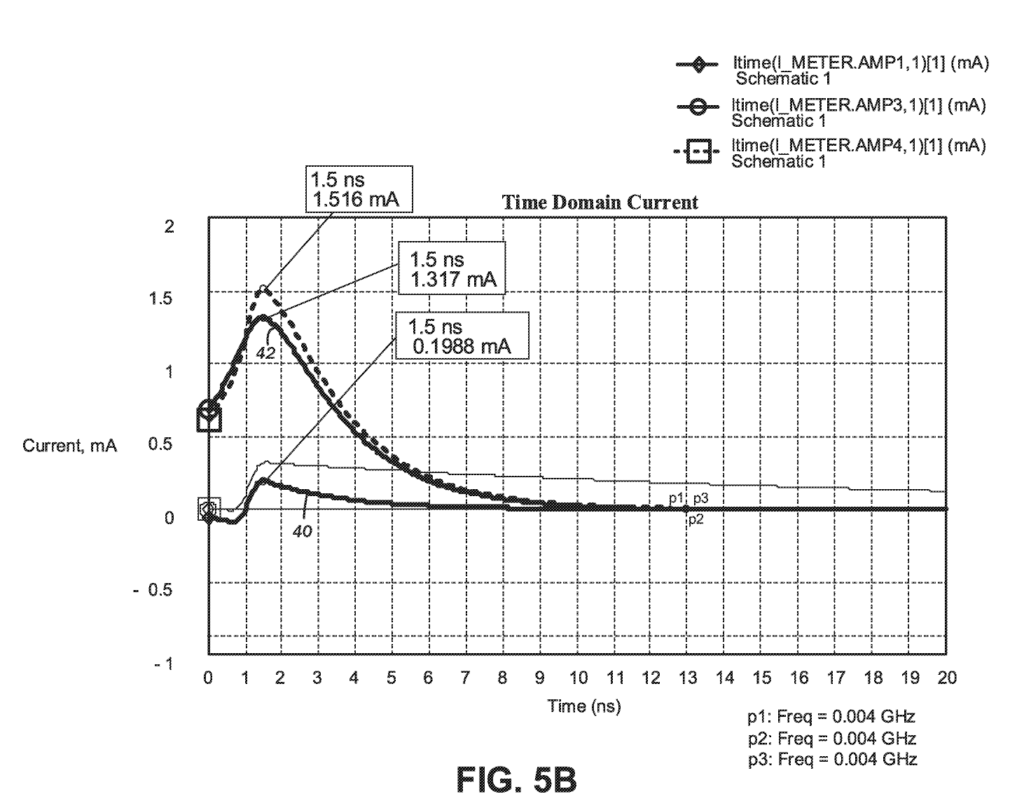

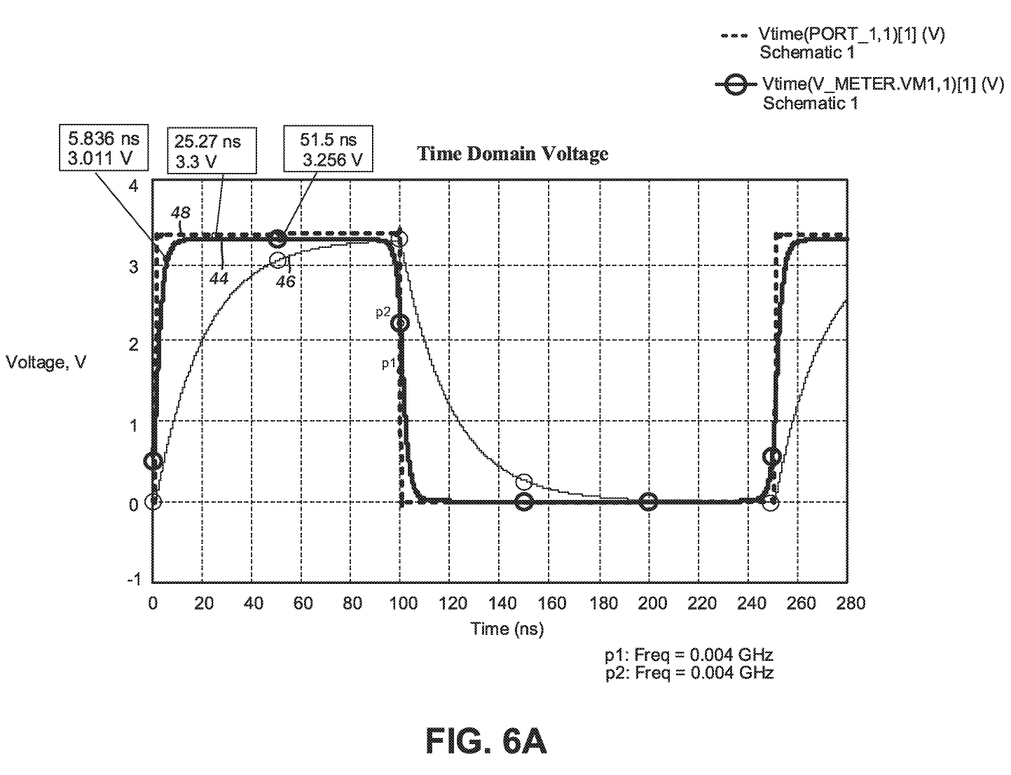

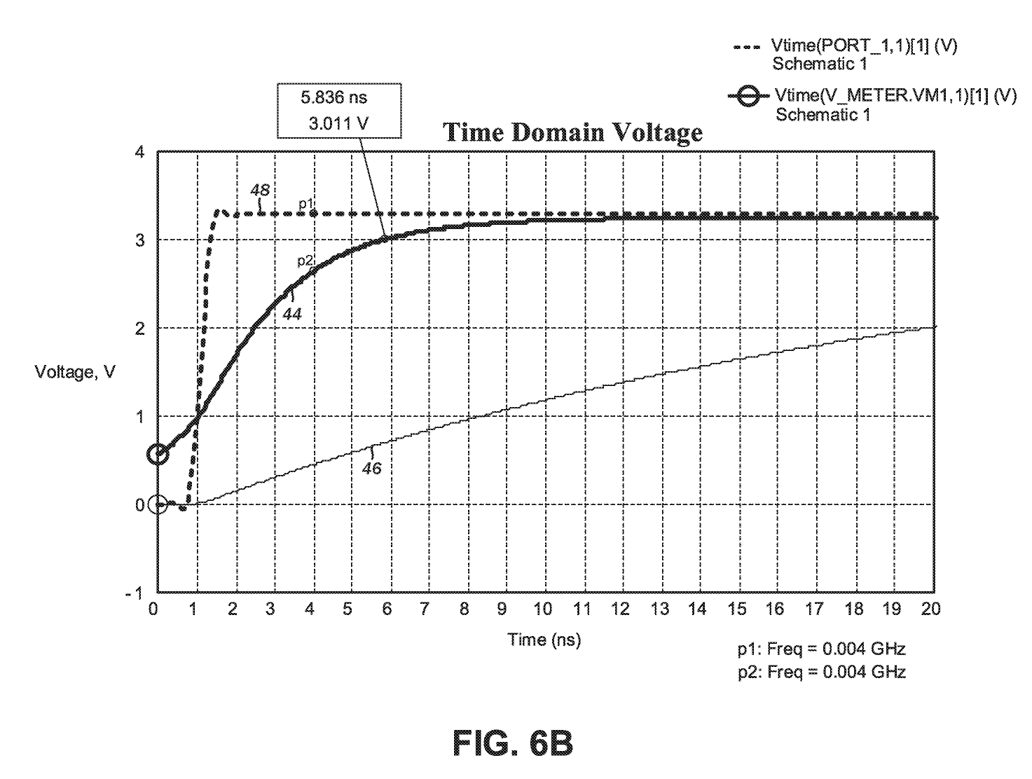

The results of simulating the performance of the speed-up circuit 10 as connected to the capacitive load 12 also being driven by the current source circuit 14 are shown in the graphics of FIGS. 5A, 5B, 6A, and 6B. Specifically, FIGS. 5A and 5B plot the simulated current values over time at specific segments of the circuit as shown in FIG. 4, with FIG. 5B showing a magnified subsection of the first twenty nanoseconds of the plot of FIG. 5A. In both graphs, there is a first plot 40 corresponding to simulated values as measured by an ammeter AMP1 in series with the resistor 36 of the current source circuit 14. Furthermore, there is a second plot 42 corresponding to simulated values as measured by an ammeter AMP3 connected to the output 16 of the speed-up circuit. As illustrated, the speed-up circuit 10 is configured such that the output current is substantially higher, at approximately 1.3 mA peak, than that generated by the current source circuit 14, which is approximately 0.19 mA peak.

The graphs of FIGS. 6A and 6B plot the simulated voltage values over time at specific segments of the circuit shown in FIG. 4. The plot of 6B is of a magnified subsection of the first 20 nanoseconds of the plot of FIG. 6A, and in both graphs there is a first plot 44 corresponding to simulated values as measured by a voltmeter VM1 connected to the input 20 of the capacitive load 12. The first plot 44 is understood to shown the simulated transient voltage response of the capacitive load 12 with both the current from the speed-up circuit 10 and the current source circuit 14. In comparison, a second plot 46 illustrates a simulated response of the capacitive load 12 without the speed-up circuit 10 being activated. As illustrated, there is a significantly reduced time constant to bring the capacitive load 12 to full charge. A third plot 48 shows the voltage signal from the current source circuit 14.

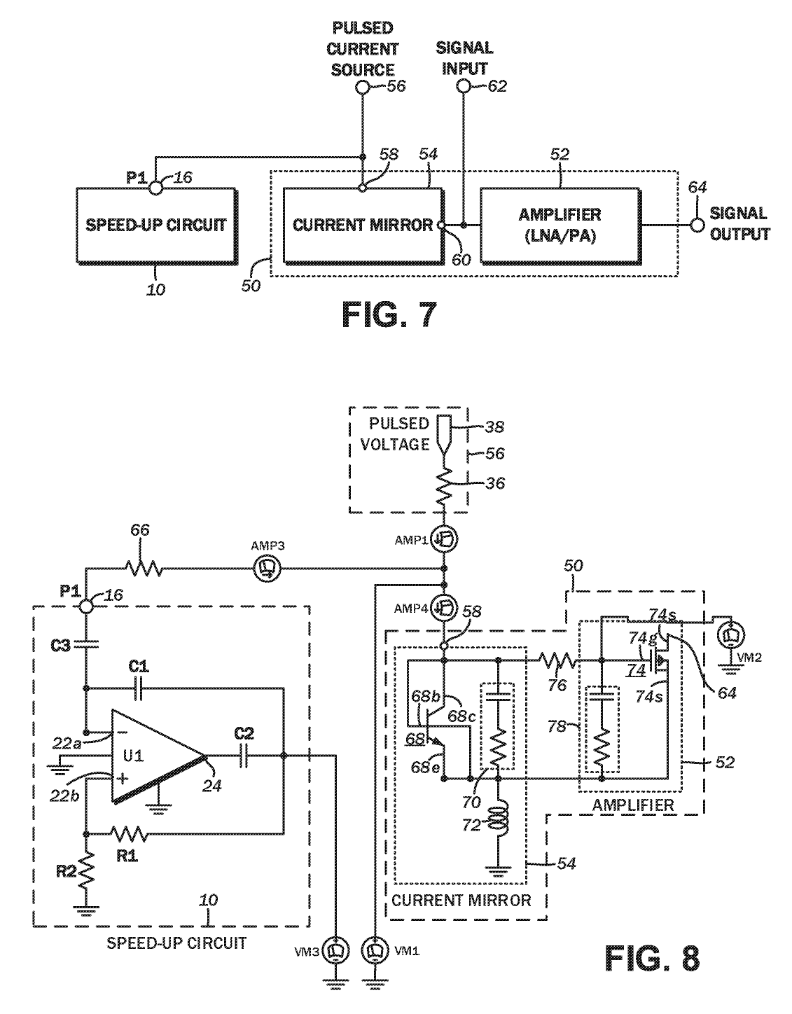

As indicated above, the present disclosure generally contemplates the use of the speed-up circuit 10 to decrease the transient response of the capacitive load 12. In the embodiment illustrated in FIG. 7, the capacitive load is a radio frequency amplifier circuit 50. As referenced herein, the radio frequency amplifier circuit 50 may be a low noise amplifier with an input connected to an antenna through an RF switch and an input of a transceiver, or a power amplifier with an input connected to the transceiver and an output connected to the antenna through the RF switch. This is by way of example only and not of limitation, however, and any other capacitive circuit where it would desirable to reduce the transient response may be readily substituted without departing from the scope of the present disclosure.

In further detail, the radio frequency amplifier circuit 50 includes an amplifier 52, which may also be referred to as a main amplifier stage. The amplifier 52 is biased and thus effectively controlled by a current mirror 54, which is turned on and turned off via a pulsed current source 56. It is understood that the pulsed current source 56 encompasses the aforementioned current source circuit 14 and the pulsed voltage source 38, and may be defined by the resistor 36. The speed-up circuit 10, and specifically the output 16 thereof, is connected to the current mirror 54 along with the pulsed current source 56. In this regard, the current mirror 54 is understood to have an enable input 58 to which the speed-up circuit 10 and the pulsed current source 56 are connected, as well as mirror output 60 that is connected to the amplifier 52. A radio frequency signal is provided to a signal input 62, and is amplified and output from a signal output 64.

Additional details of the circuit shown in FIG. 7 will be considered with reference to the schematic diagram of FIG. 8. Again, the speed-up circuit 10 includes the operational amplifier U1 with the inverting input 22a, non-inverting input 22b, and the single-ended output 24. The capacitors C1 and C3 are connected to the inverting input 22a, while the resistors R1 and R2 are connected to the non-inverting input 22b. The capacitor C2 connected to the single-ended output is connected to both the capacitor C1 and the resistor R1. The resistor R2 is connected to ground, while the capacitor C3 is connected to the output 16. The values of these passive components are as set forth above.

The pulsed current source 56, which is generally defined by the pulsed voltage source 38 and the resistor 36, is connected to the current mirror 54, as is the speed-up circuit 10. Between the speed-up circuit 10 and the current mirror 54 there may be an interconnect resistance or resistor 66. This resistance may be substantially lower than the current source resistance or resistor 36, and as will be described in further detail below, may be as low as 1Ω, though it may be as high as 10 kΩ.

As described above, the radio frequency amplifier circuit 50 includes the current mirror 54 and the amplifier 52. In one embodiment, the current mirror 54 is comprised of a mirror transistor 68 with a base 68b, an emitter 68e, and a collector 68c. The collector 68c corresponds to the enable input 58 of the current mirror 54, and is connected to the speed-up circuit 10 and the pulsed current source 56. The mirror transistor 68 is characterized by parasitic capacitance and resistive loss 70, along with an inductance 72 that corresponds to bond wires connecting the mirror transistor 68 and the amplifier transistor 74 to ground. For purposes of simulating the performance of this circuit, the resistive loss is set to be 0.2Ω, and a capacitance of 10 pF. The inductance is set to be 0.5 nH.

Along these lines, the amplifier 52 includes an amplifier transistor 74 with a gate 74g, a source 74s, and a drain 74d. The gate 74g is connected to the collector 68c of the mirror transistor 68 over a mirror resistor 76, which, for purposes of simulating the performance of the circuit, is understood to be 10 kΩ. The mirror resistor 76 is understood to serve RF-decoupling purposes. Like the mirror transistor 68, the amplifier transistor is understood to define a parasitic capacitance and resistive loss 78. The same capacitance value of 2 pf and the same resistance of 0.2Ω may be set for the parasitic capacitance and resistive loss 78. The source 74s and the emitter 68e are be tied to ground together through the aforementioned inductance 72. The drain 78d, on the other hand, may correspond to the signal output 64.

Although the mirror transistor 68 is depicted as a bipolar junction transistor, and the amplifier transistor 74 is depicted as a field effect transistor, this is by way of example only and not of limitation. Any suitable type of transistor may be substituted without departing from the scope of the present disclosure. In this regard, although the foregoing makes reference to certain features that are specific to field effect transistors such as the gate, the source, and the drain, or specific to bipolar junction transistors such as the base, the emitter, and the collector, to the extent different types of transistors are substituted, those features are understood to have corollary features for such alternative transistor types, Furthermore, the transistors and the related circuitry may be fabricated using silicon-based technologies such as bulk CMOS (complementary metal oxide semiconductor), SOI (silicon-on-insulator), and BiCMOS (integration of bipolar junction and complementary metal oxide semiconductor fabrication technologies). Other semiconductor technologies such as GaAs (gallium arsenide) may also be utilized.

When the operational amplifier U1 is enabled but the pulsed current source 56 is not generating the pulsed current, there is no current flowing to the current mirror 54. However, once the pulsed current is flowing to the mirror transistor 68, the current generated by the operational amplifier U1 is added thereto and also flows to the same. The pulsed current is understood to have an activated state and a deactivated state, and the added current from the speed-up circuit 10 is generated and flowing to current mirror 54 during the transition from the deactivated state to the activated state. The speed-up circuit 10 has its own resistor-capacitor (RC) time constant, and the current flow increase therefrom corresponds thereto.

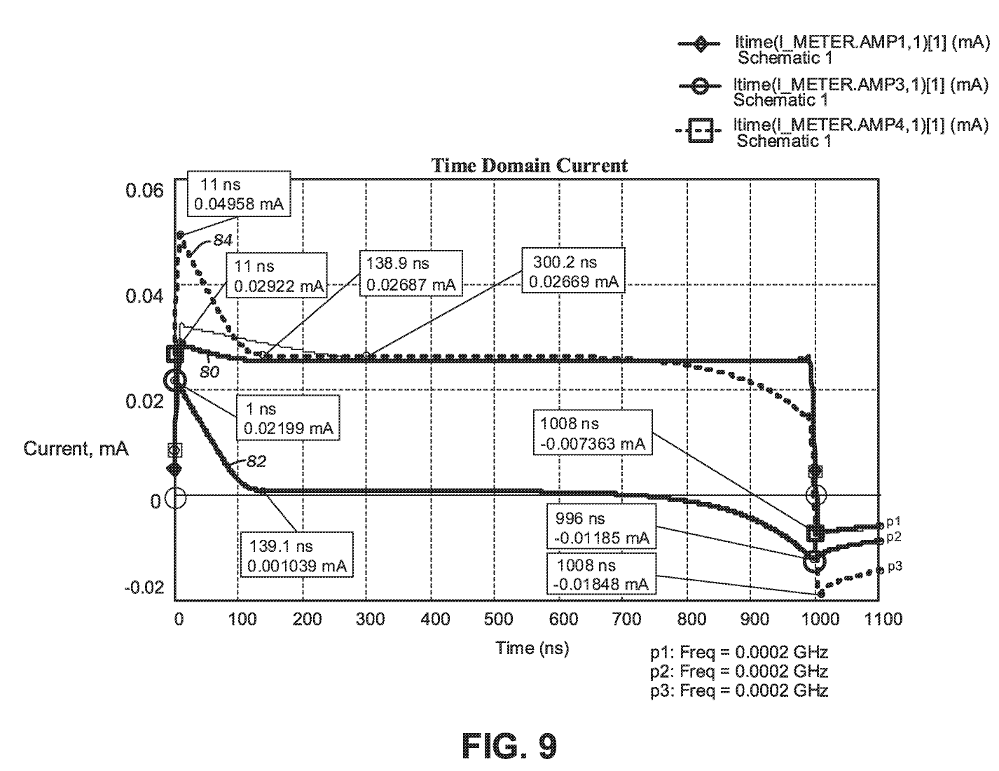

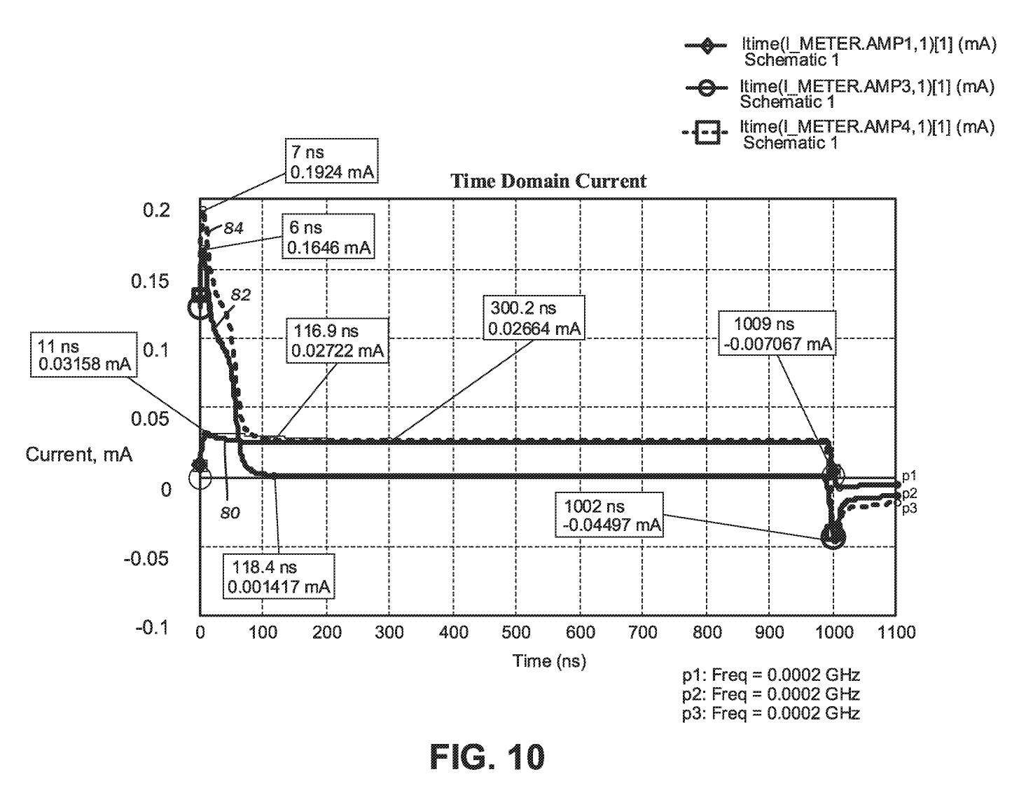

The results of simulating the performance of the radio frequency amplifier circuit 50 with the speed-up circuit 10 connected thereto are shown in the graphics of FIGS. 9-10 and 11-12. As briefly noted above, the interconnect resistance or resistor 66 that is interposed between the speed-up circuit 10 and the radio frequency amplifier circuit 50 may be as high, or lower than the current source resistance or resistor 36. In this regard, FIG. 9 plots the simulated current values measured over time at various ammeters throughout the circuit, with the interconnect resistance or resistor 66 set to 10 kΩ. FIG. 10, in comparison, plots the simulated current values at the same ammeters with the interconnect resistance or resistor 66 set to 1Ω. The graphs in both FIG. 9 and FIG. 10 includes a first plot 80 corresponding to simulated values as measured the ammeter AMP1 in series with the resistor 36 of the pulsed current source 56. There is also a second plot 82 corresponding to the simulated values as measured by the ammeter AMP3 and shows the current flowing from the speed-up circuit 10 to the current mirror 54. The graphs also include a third plot 84 corresponding to the simulated values as measured by the ammeter AMP4, which represents the combined current from the speed-up circuit 10 and the pulsed current source 56 to the current mirror 54.

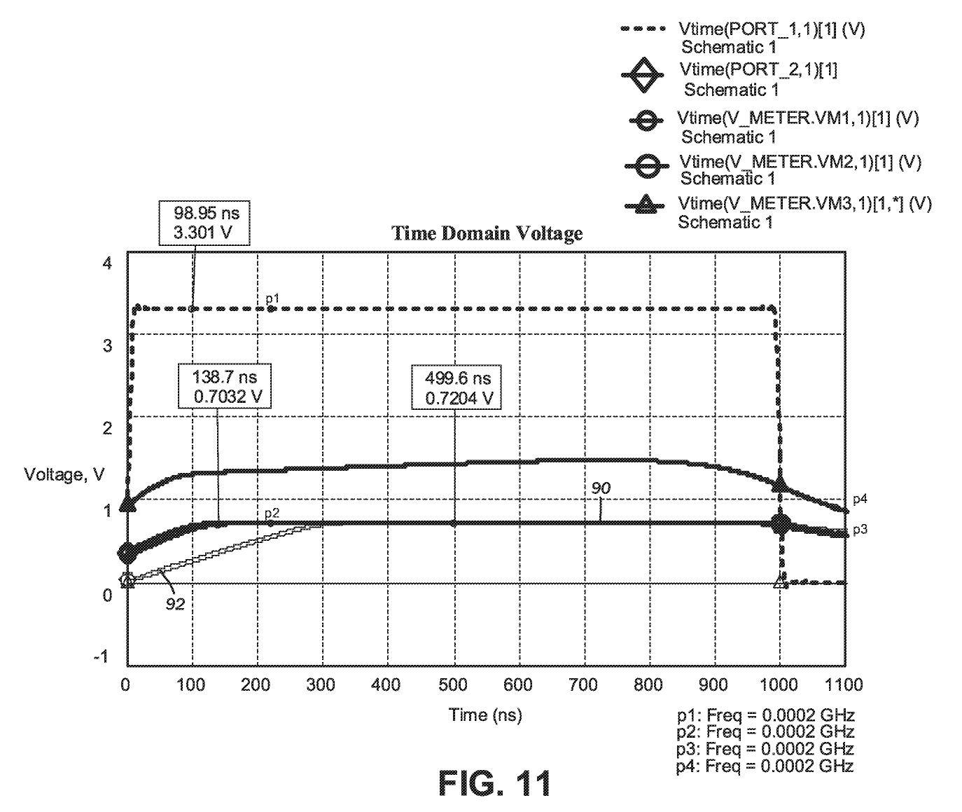

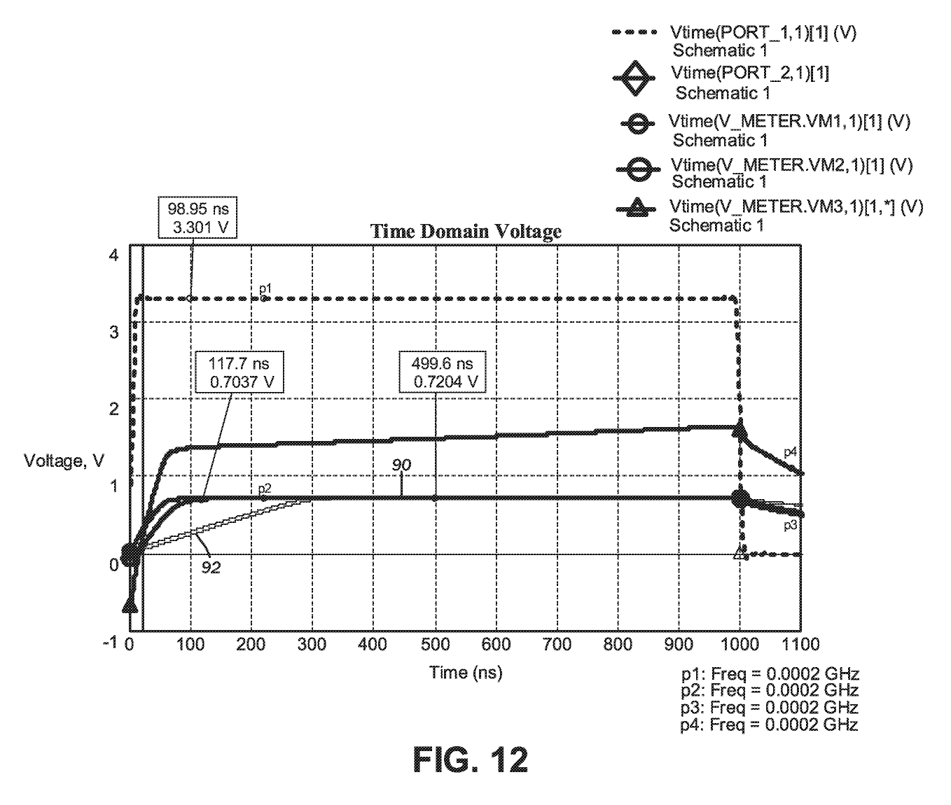

The graphs of FIGS. 11 and 12 plot the simulated voltage values measured over time at specific segments of the circuit shown in FIG. 8. Both graphs include a first plot 90 of the simulated voltage measured by the voltmeter VM1 over time, corresponding to the enable input 58 of the current mirror 54. Additionally, both graphs also include a second plot 92 of the simulated voltage with the speed-up circuit 10 omitted. As illustrated, the transient response time of the current mirror 54 with the 1Ω interconnect resistance or resistor 66 is substantially shorter than that with the 10 kΩ interconnect resistance or resistor 66. The omission of the speed-up circuit 10 results in a significant increase in the transient response time of the current mirror 54 to reach the full voltage.

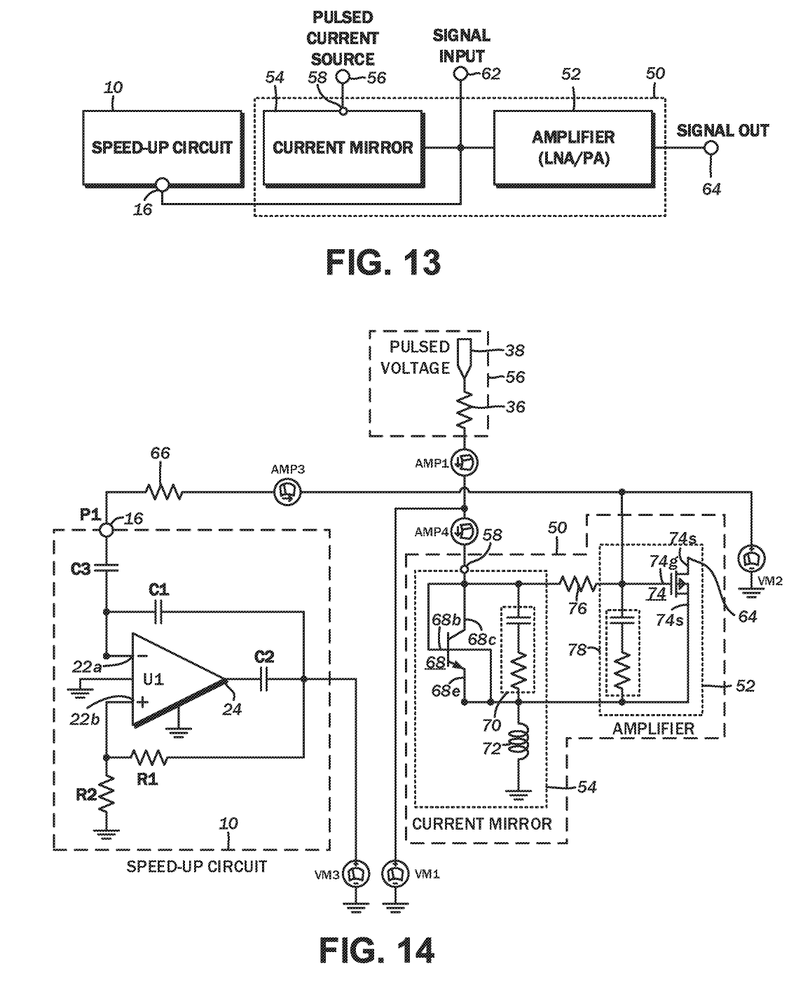

FIG. 13 illustrates an alternative configuration in which the speed-up circuit 10 is connected directly to the amplifier 52. In this embodiment, the radio frequency amplifier circuit 50 likewise includes the amplifier 52 that is biased by the current mirror 54. The amplifier 52 and the current mirror 54 are turned on and turned off via the pulsed current source 56, which encompasses the aforementioned current source circuit 14 and the pulsed voltage source 38. The pulsed current source 56 may be defined by the resistor 36. The speed-up circuit 10, and specifically the output 16 thereof, is connected to the input of the amplifier 52, as is the current mirror 54. The current mirror 54 includes the enable input 58, to which the pulsed current source 56 is connected. A radio frequency signal is provided to a signal input 62, and is amplified and output from a signal output 64.

FIG. 14 shows additional details of the circuit shown in FIG. 13. Again, the speed-up circuit 10 includes the operational amplifier U1 with the inverting input 22a, non-inverting input 22b, and the single-ended output 24. The capacitors C1 and C3 are connected to the inverting input 22a, while the resistors R1 and R2 are connected to the non-inverting input 22b. The capacitor C2 connected to the single-ended output is connected to both the capacitor C1 and the resistor R1. The resistor R2 is connected to ground, while the capacitor C3 is connected to the output 16. The values of these passive components are as set forth above.

The pulsed current source 56, which is generally defined by the pulsed voltage source 38 and the resistor 36, is connected to the current mirror 54, as is the speed-up circuit 10. Between the speed-up circuit 10 and the current mirror 54 there is the interconnect resistance or resistor 66. This resistance may be substantially lower than the current source resistance or resistor 36, and may be as low as 1Ω, though it may be as high as 10 kΩ.

The radio frequency amplifier circuit 50 includes the current mirror 54 and the amplifier 52. In one embodiment, the current mirror 54 is comprised of a mirror transistor 68 with the base 68b, the emitter 68e, and the collector 68c. The collector 68c corresponds to the enable input 58 of the current mirror 54. The mirror transistor 68 is characterized by parasitic capacitance and resistive loss 70, along with an inductance 72 that corresponds to bond wires connecting the mirror transistor 68 and the amplifier transistor 74 to ground. For purposes of simulating the performance of this circuit, the resistive loss is set to be 0.2Ω, and a capacitance of 10 pF. The inductance is set to be 0.5 nH.

Again, the amplifier 52 includes the amplifier transistor 74 with the gate 74g, a source 74s, and the drain 74d. The gate 74g is connected to the collector 68c of the mirror transistor 68 over a mirror resistor 76, which, for purposes of simulating the performance of the circuit, is understood to be 10 kΩ, and serves RF-decoupling purposes. Like the mirror transistor 68, the amplifier transistor is understood to define a parasitic capacitance and resistive loss 78. The same capacitance value of 2 pf and the same resistance of 0.2Ω may be set for the parasitic capacitance and resistive loss 78. The source 74s and the emitter 68e are be tied to ground together through the aforementioned inductance 72. The drain 78d, on the other hand, may correspond to the signal output 64.

In the illustrated embodiment of FIG. 14, the speed-up circuit 10, and hence the interconnect resistance or resistor 66, is directly connected to the amplifier 52, and specifically the gate 74g of the amplifier transistor 74. Because of its high impedance, the speed-up circuit 10 is envisioned not to load the gate 74g of the amplifier transistor 74 over a wide range of operating frequencies.

When the operational amplifier U1 is enabled but the pulsed current source 56 is not generating the pulsed current, there is no current flowing to the amplifier 52. However, once the pulsed current is flowing to the mirror transistor 68 and then to the amplifier transistor 74, the current generated by the operational amplifier U1 is added. The pulsed current has an activated state and a deactivated state, and the added current from the speed-up circuit 10 is generated and flowing to the amplifier 52 during the transition from the deactivated state to the activated state. The speed-up circuit 10 has its own resistor-capacitor (RC) time constant, and the current flow increase from the speed-up circuit 10 corresponds thereto.

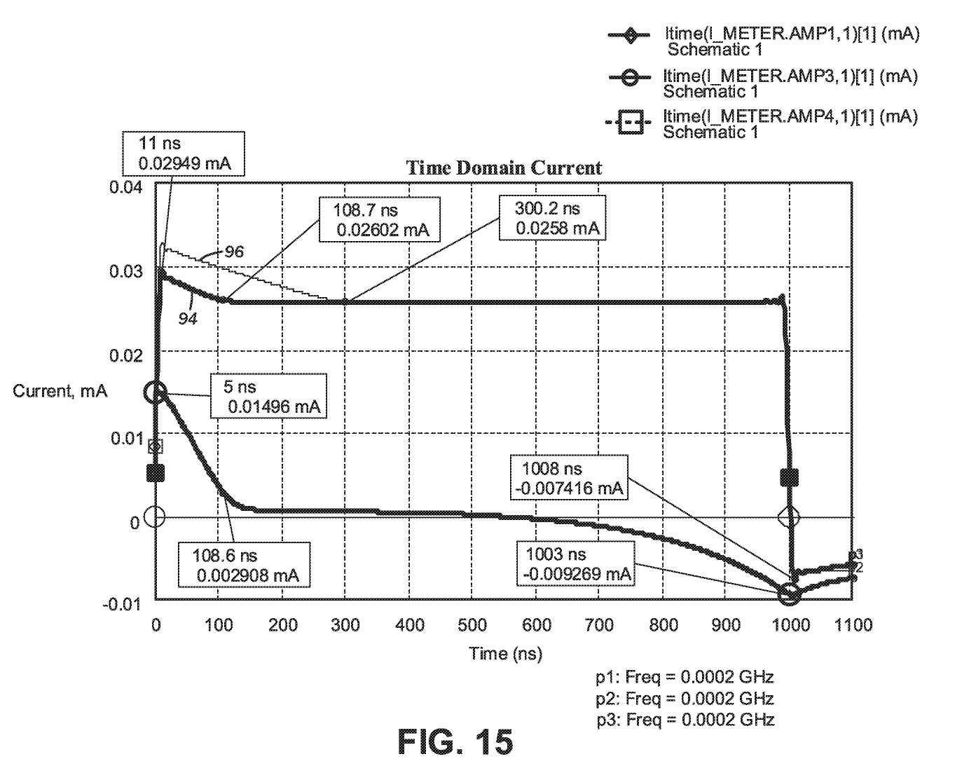

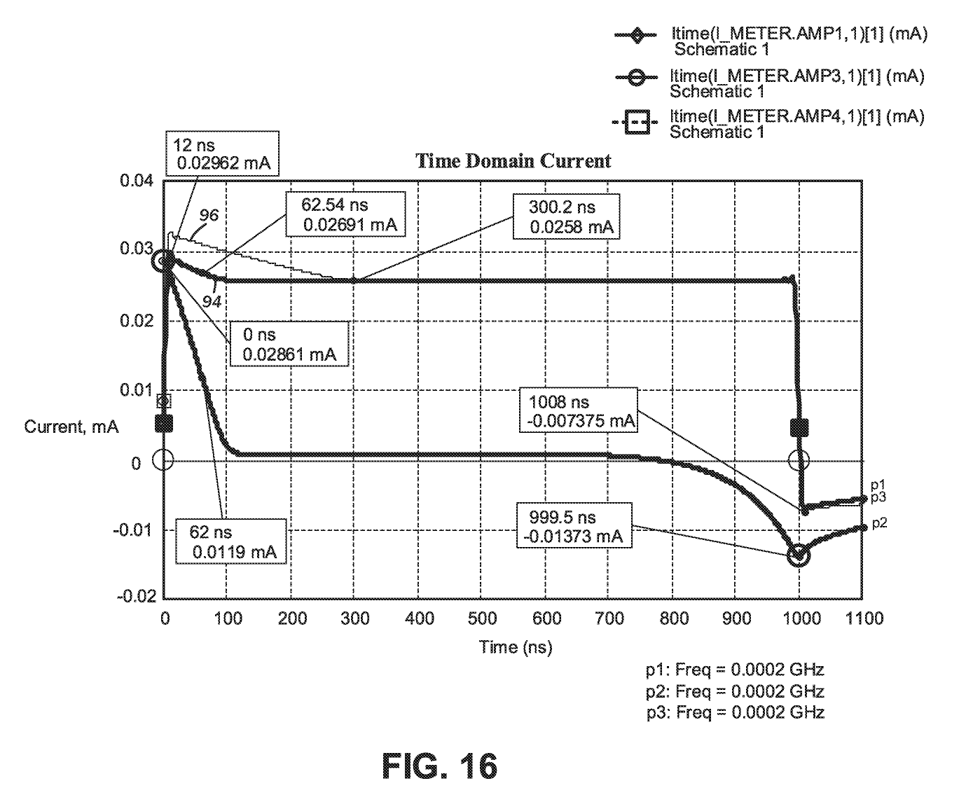

The results of simulating the performance of the radio frequency amplifier circuit 50 with the speed-up circuit 10 connected thereto are shown in the graphics of FIGS. 15-16 and 17-18. As in the embodiment of the circuits discussed above, the interconnect resistance or resistor 66 that is interposed between the speed-up circuit 10 and the radio frequency amplifier circuit 50 may be as high as, or lower than the current source resistance or resistor 36. The graph of FIG. 15 plots the simulated current values measured over time at various ammeters throughout the circuit, with the interconnect resistance or resistor 66 set to 10 kΩ. FIG. 16 plots the simulated current values at the same ammeters with the interconnect resistance or resistor 66 set to 1Ω. The graphs each include a first plot 94 corresponding to simulated values as measured the ammeter AMP1 in series with the resistor 36 of the pulsed current source 56, where the speed-up circuit 10 is activated. There is also a second plot 96 corresponding to the simulated values as measured by the ammeter AMP1 without the speed-up circuit 10, which by way comparison shows the substantial reduction in transient current response as inclusion of the speed-up circuit 10 on one hand, and the use of a high or low interconnect resistance or resistor 66.

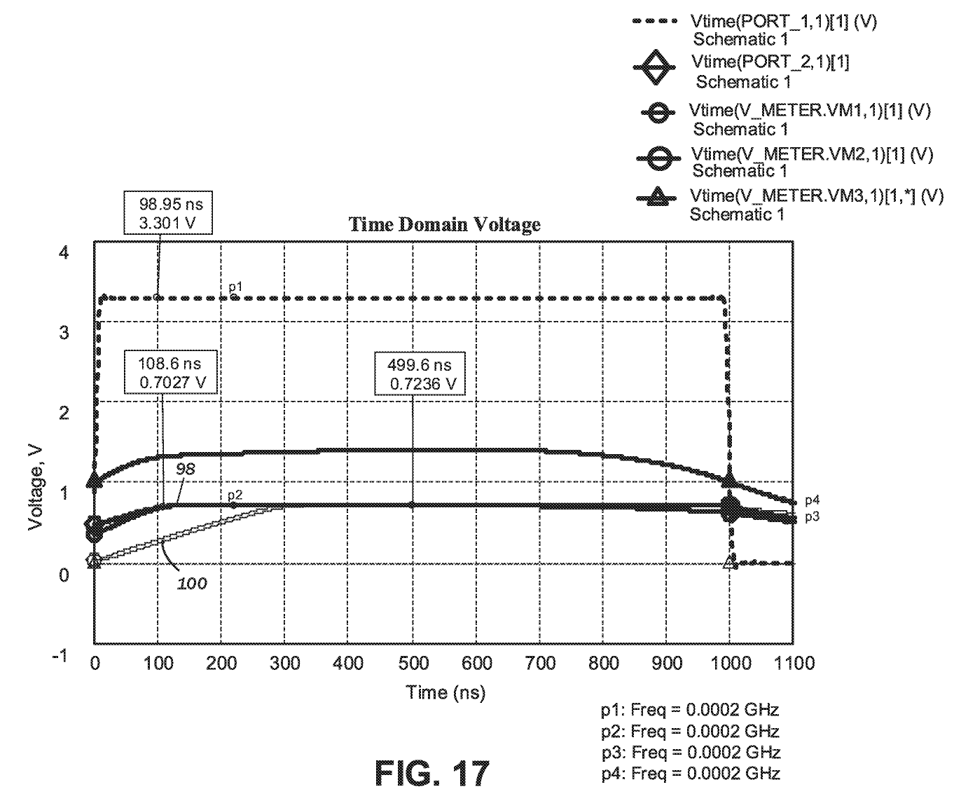

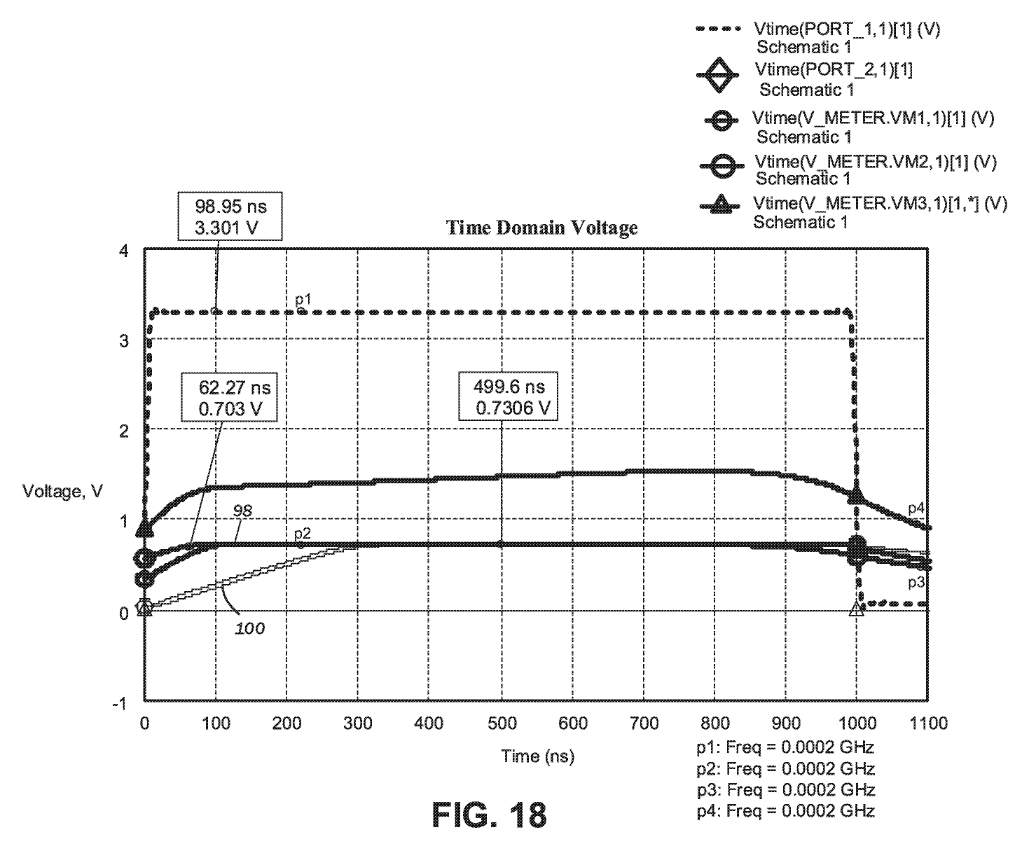

The graphs of FIGS. 17 and 18 plot the simulated voltage values measured over time at specific segments of the circuit shown in FIG. 14. Both graphs include a first plot 98 of the simulated voltage measured by the voltmeter VM1 over time, corresponding to the enable input 58 of the current mirror 54. Additionally, both graphs also include a second plot 100 of the simulated voltage with the speed-up circuit 10 omitted. As illustrated, the transient response time of the current mirror 54 with the 1Ω interconnect resistance or resistor 66 is substantially shorter than that with the 10 kΩ interconnect resistance or resistor 66. The omission of the speed-up circuit 10 results in a significant increase in the transient response time, which is understood to reducing the switching/enabling time of the amplifier 52.

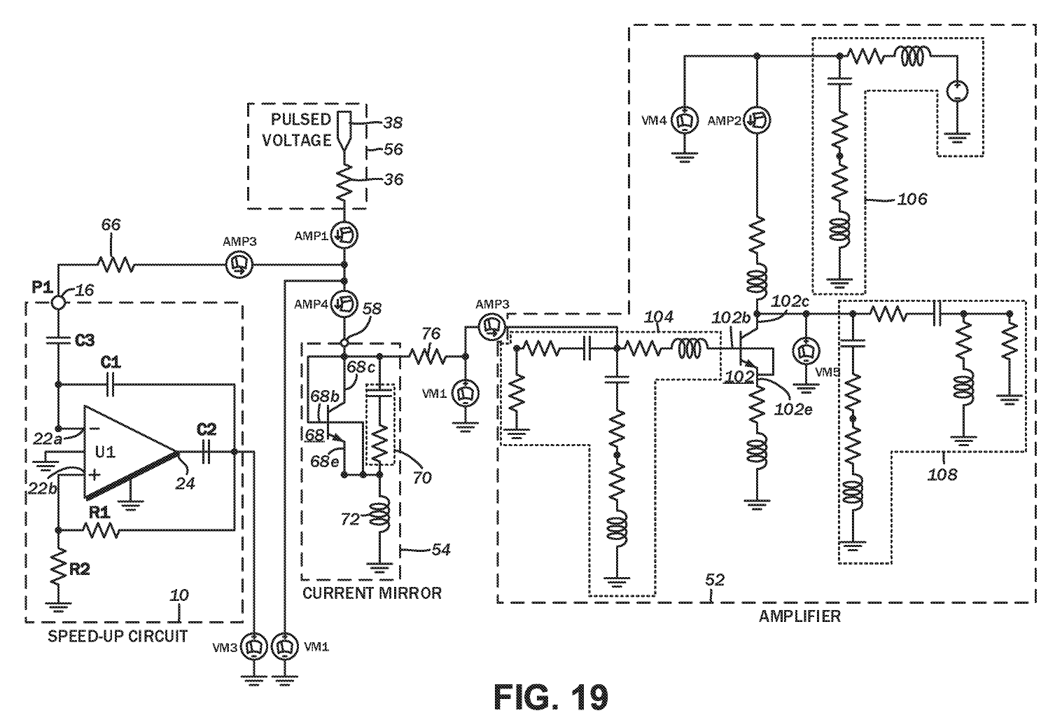

Referring now to FIG. 19, another embodiment of the radio frequency amplifier circuit 50 is generally comprised of the aforementioned speed-up circuit 10, the current mirror 54, and the amplifier 52. As in the other embodiments described above, the speed-up circuit 10 includes the operational amplifier U1 with the inverting input 22a, non-inverting input 22b, and the single-ended output 24. The capacitors C1 and C3 are connected to the inverting input 22a, while the resistors R1 and R2 are connected to the non-inverting input 22b. The capacitor C2 connected to the single-ended output is connected to both the capacitor C1 and the resistor R1. The resistor R2 is connected to ground, while the capacitor C3 is connected to the output 16. The values of these passive components are as set forth above.

The pulsed current source 56, which is generally defined by the pulsed voltage source 38 and the resistor 36, is connected to the current mirror 54, as is the speed-up circuit 10. In some cases, the current mirror 54 may be deemed to be part of the amplifier 52, as biasing of the amplifier components is provided thereby. Between the speed-up circuit 10 and the current mirror 54 there is the interconnect resistance or resistor 66. This resistance may be substantially lower than the current source resistance or resistor 36, and may be as low as 1Ω, though it may be as high as 10 kΩ. The current mirror 54 is comprised of a mirror transistor 68 with the base 68b, the emitter 68e, and the collector 68c. The collector 68c corresponds to the enable input 58 of the current mirror 54, and is connected to the speed-up circuit 10. The mirror transistor 68 is characterized by parasitic capacitance and resistive loss 70, along with an inductance 72 that corresponds to bond wires connecting the mirror transistor 68 and the amplifier transistor 74 to ground. For purposes of simulating the performance of this circuit, the resistive loss is set to be 0.2Ω, and a capacitance of 10 pF. The inductance is set to be 0.5 nH.

The amplifier 52 is generally comprised of the amplifier transistor 102 with a base 102b, a collector 102c, and an emitter 102e. Additionally, the amplifier 52 includes an input matching circuit 104 that is connected to the base 102b, and to the current mirror 54. The input matching circuit 104 is connected to the current mirror 54 over the interconnect resistance or resistor 66 as described above, and for purposes of simulating the performance of the radio frequency amplifier circuit 50, it is understood to have a high value in the 10 kΩ range. The amplifier 52 also includes a biasing circuit 106 connected to the collector 102c. Also connected to the collector 102c is an output matching circuit 108 that impedance matches the amplifier transistor 102 to the downstream connection, e.g., a transceiver input, or an antenna via an RF switch.

When the operational amplifier U1 is enabled but the pulsed current source 56 is not generating the pulsed current, there is no current flowing to the amplifier 52. However, once the pulsed current is flowing to the mirror transistor 68 and then to the amplifier transistor 74, the current generated by the operational amplifier U1 is added. The pulsed current has an activated state and a deactivated state, and the added current from the speed-up circuit 10 is generated and flowing to the amplifier 52 during the transition from the deactivated state to the activated state. The speed-up circuit 10 has its own resistor-capacitor (RC) time constant, and the current flow increase from the speed-up circuit 10 corresponds thereto.

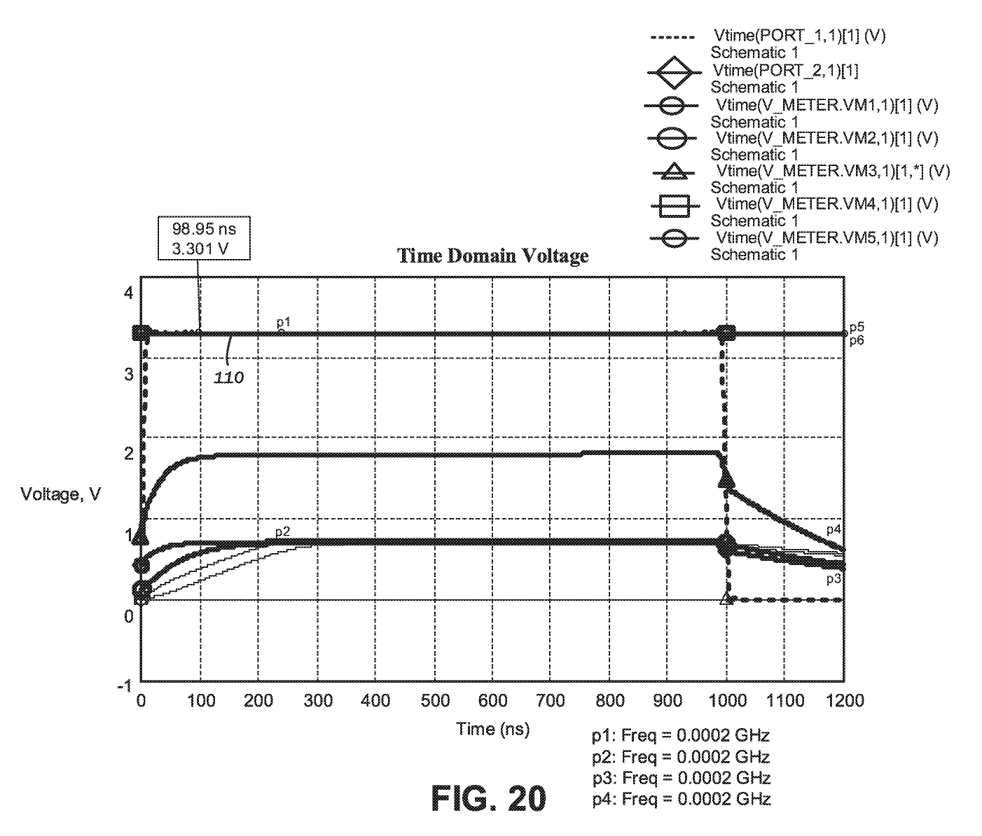

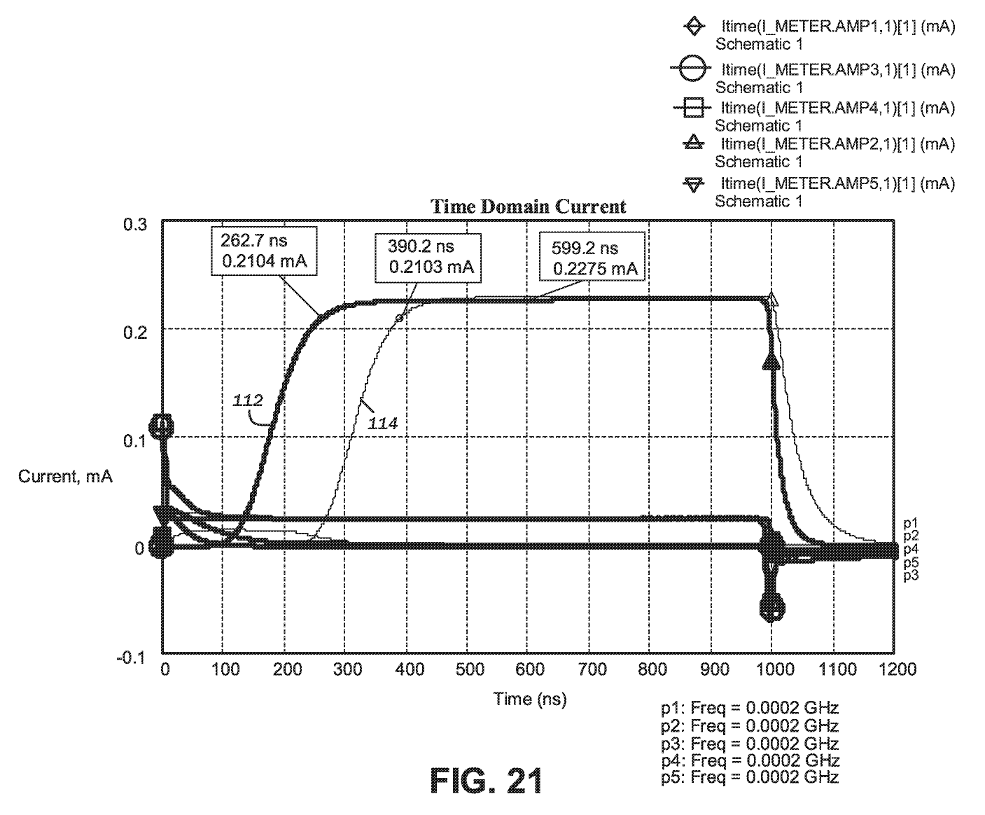

The graph of FIG. 20 shows the voltage response of the amplifier 52, as measured by the various simulated voltmeters positioned throughout the circuit. A first plot 110 represents the pulsed voltage from the pulsed current source 56 as measured by the voltmeter VM1. The graph of FIG. 21 shows the corresponding current at various simulated ammeters positioned throughout the circuit over the same time period. As shown, there is a delay between the activation of the pulsed current source 56 and when the current of the amplifier transistor 74 reaches 90% of its steady state current. The first plot 112 of the graph of FIG. 21 illustrates the current measured by the ammeter AMP2 from the biasing circuit 106 to the amplifier transistor 102, where performance of the radio frequency amplifier circuit 50 is improved with the speed-up circuit 10. A second plot 114 of the same graph shows the current response without the speed-up circuit 10, and there is understood to be a delay of approximately 100 ns. The current is understood to increase only upon the voltage at the base 102b reaching a threshold.

As will be appreciated by those having ordinary skill in the art, the bias point of amplifier circuits, particularly radio frequency amplifiers, are set indirectly with the current mirror 54, and the current mirror 54 is biased from a pulsed current source. Both the mirror transistor 68 and the amplifier transistor 102 are understood to have a substantial capacitance, and so because the biasing of the mirror transistor 68 is delayed, so is the biasing of the amplifier transistor 102. The speed-up circuit 10 of the present disclosure is contemplated to provide larger currents to the mirror transistor 68 and the amplifier transistor 102 when the control signal changes from on to off, or vice versa. Accordingly, charging and discharging times of the amplifier 52 are faster, so the amplifier transistor 102 reaches normal bias conditions faster.

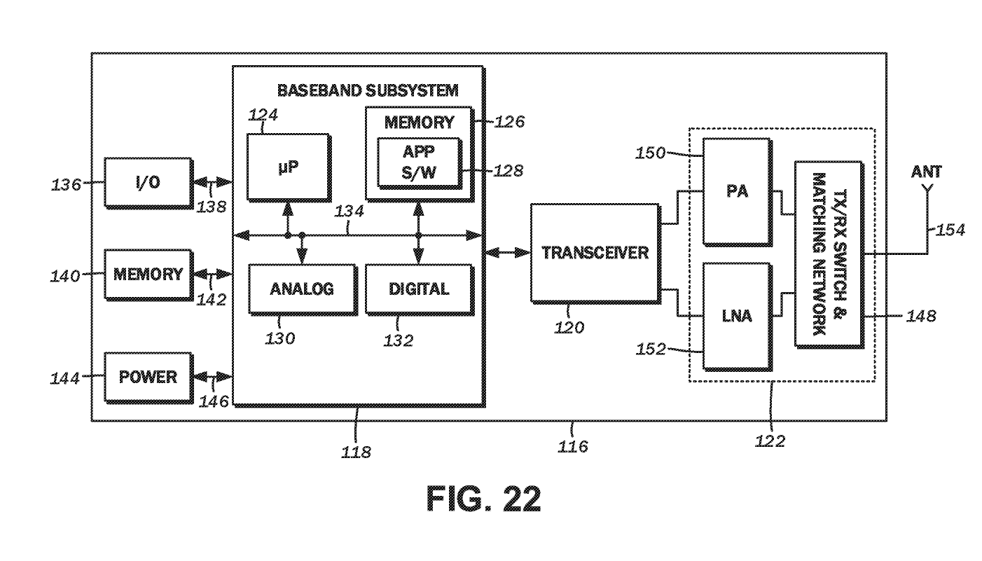

FIG. 22 is a block diagram illustrating a simplified wireless communications device 116 in which an embodiment of the radio frequency amplifier circuit 50 in accordance with the present disclosure may be implemented. In various embodiments, the wireless communications device 116 can be a cellular telephone. However, the amplifier circuit may be utilized in any device that incorporates an amplifier, and fast transient responses are desired. The wireless communications device 116 illustrated in FIG. 22 is intended to be a simplified example of a cellular telephone and to illustrate one of many possible applications in which the amplifier 52, including the speed-up circuit 10 can be implemented. One having ordinary skill in the art will understand the operation of a cellular telephone, and, as such, implementation details are omitted.

The wireless communications device 116 includes a baseband subsystem 118, a transceiver 120, and a front end module 122. Although omitted from FIG. 22, the transceiver 120 includes modulation and upconversion circuitry for preparing a baseband information signal for amplification and transmission, and includes filtering and downconversion circuitry for receiving and downconverting a radio frequency signal to a baseband information signal to recover data. The details of the operation of the transceiver 120 are known to those skilled in the art.

The baseband subsystem 118 generally includes a processor 124, which can be a general purpose or special purpose microprocessor, memory 126, application software 128, analog circuit elements 130, and digital circuit elements 132, connected over a system bus 134. The system bus 134 can include the physical and logical connections to couple the above-described elements together and enable their interoperability.

An input/output (I/O) element 136 is connected to the baseband subsystem 118 over a connection 138, a memory element 140 is coupled to the baseband subsystem 118 over a connection 142 and a power source 144 is connected to the baseband subsystem 118 over connection 146. The I/O element 136 can include, for example, a microphone, a keypad, a speaker, a pointing device, user interface control elements, and any other device or system that allows a user to provide input commands and receive outputs from the wireless communications device 116.

The memory 126 can be any type of volatile or non-volatile memory, and in an embodiment, can include flash memory. The memory element 140 can be permanently installed in the wireless communications device 116, or can be a removable memory element, such as a removable memory card.

The power source 144 can be, for example, a battery, or other rechargeable power source, or can be an adaptor that converts AC power to the correct voltage used by the wireless communications device 116. In an embodiment, the power source can be a battery that provides a nominal voltage output of approximately 3.6 volts (V). However, the output voltage range of the power source can range from approximately 3.0 to 6.0 V.

The processor 124 can be any processor that executes the application software 128 to control the operation and functionality of the wireless communications device 116. The memory 126 can be volatile or non-volatile memory, and in an embodiment, can be non-volatile memory that stores the application software 128.

The analog circuit elements 130 and the digital circuit elements 132 include the signal processing, signal conversion, and logic that convert an input signal provided by the I/O element 136 to an information signal that is to be transmitted. Similarly, the analog circuit elements 130 and the digital circuit elements 132 include the signal processing, signal conversion, and logic that convert a received signal provided by the transceiver 120 to an information signal that contains recovered information. The digital circuit elements 132 can include, for example, a Digital Signal Processor (DSP), a Field Programmable Gate Array (FPGA), or any other processing device. Because the baseband subsystem 118 includes both analog and digital elements, it is sometimes referred to as a mixed signal circuit.

The front end module 122 is generally comprised of components belonging to a transmit signal chain, components belonging to a receive signal chain, and a switch 148. For purposes of simplification, the transmit signal chain is generally represented by a power amplifier 150, while the receive signal chain is generally represented by a low noise amplifier 152. The switch 148 interconnects the power amplifier 150 and the low noise amplifier 152 to an antenna 154. Each or either of the power amplifier 150 and the low noise amplifier 152 may include the current mirror 54 and the speed-up circuit 10 as described above. The front end module 122 depicted in FIG. 22 is understood to be for a single wireless operating mode, and those having ordinary skill in the art will appreciate that a conventional wireless communications device 116 has multiple wireless operating modes conforming to different standards. Accordingly, there may be multiple front end modules 122 particularly configured for each operating mode, or one front end module 122 with multiple constituent components for each operating mode. Along these lines, these different operating modes may utilize more than one antenna at a time (diversity mode operation), so the single antenna 154 is presented by way of example only and not of limitation.

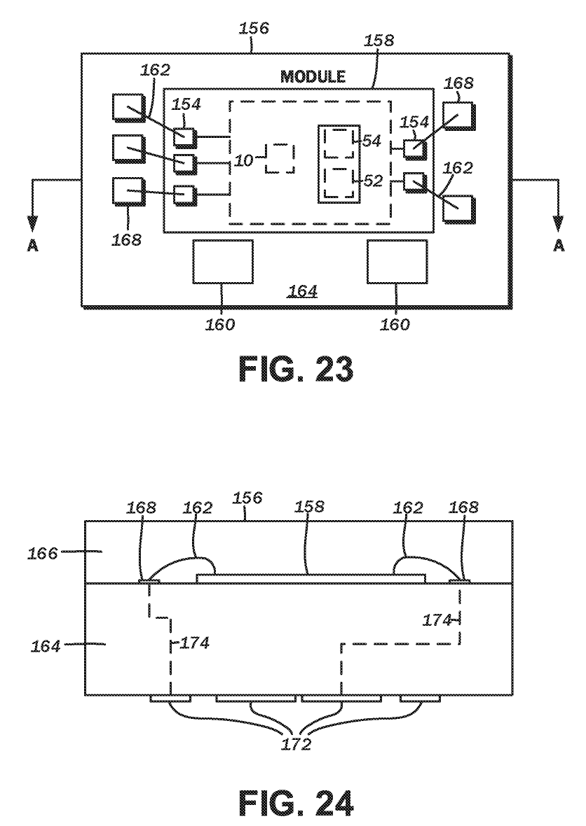

FIG. 23 is a schematic diagram of an embodiment of a packaged radio frequency communications module 156, while FIG. 24 is a schematic diagram of a cross-section of the packaged radio frequency communications module 156 taken along axis A-A of FIG. 23. The packaged radio frequency communications module 156 includes an integrated circuit or die 158, surface mount components 160, wire bonds 162, a package substrate 164, and an encapsulation structure 166. The package substrate 164 includes pads 168 formed from conductors disposed therein. Additionally, the die 158 includes pads 170, and the wire bonds 162 are used to electrically connect the pads 170 of the die 158 to the pads 168 of the package substrate 164.

The die 158 includes the radio frequency amplifier circuit 50, of the present disclosure formed therein. Specifically, the die 158 includes the speed-up circuit 10, the current mirror 54, and the amplifier 52. The foregoing components on the die 158 are understood to be as described above. The die 158 is mounted to the package substrate 164 as shown, though it may be configured to receive a plurality of additional components such as the surface mount components 160. These components include additional integrated circuits as well as passive components such as capacitors, inductors, and resistors.

As shown in FIG. 24, the packaged radio frequency communications module 156 is shown to include a plurality of contact pads 172 disposed on the side of the packaged radio frequency communications module 156 opposite the side used to mount the die 158. Configuring the packaged radio frequency communications module 156 in this manner can aid in connecting the same to a circuit board of the wireless communications device 116. The example contact pads 172 can be configured to provide radio frequency signals, bias signals, power low voltage(s) and or power high voltage(s) to the die 158 and/or the surface mount components 160. The electrical connections between the contact pads 172 and the die 158 can be facilitated by connections 174 through the package substrate 164. The connections 174 can represent electrical oaths formed through the package substrate 164, such as connections associated with vias and conductors of a multilayer laminated package substrate.

In some embodiments, the packaged radio frequency communications module 156 can also include or more packaging structures to, for example, provide protection and/or to facilitate handling of the packaged radio frequency communications module 156. Such a packaging structure can include overmold or encapsulation structure 166 formed over the package substrate 164 and the components and die(s) disposed thereon.

It will be understood that although the packaged radio frequency communications module 156 is described in the context of electrical connections based on wire bonds, one or more features of the present disclosure can also be implemented in other packaging configurations, including, for example, flip-chip configurations.

The particulars shown herein are by way of example and for purposes of illustrative discussion of the embodiments of the speed-up circuits and the amplifier circuits including such speed-up circuits, and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A speed-up circuit connectable to a capacitive load to reduce charging time thereof from a pulsed current source connected thereto, the speed-up circuit comprising:
a first circuit node connectable to the capacitive load; and
an operational amplifier circuit connected to the first circuit node and configured as a low resistance voltage source, added current from the operational amplifier flowing to the capacitive load through the first circuit node for a predetermined duration between the pulsed current source transitioning between a deactivated state and an activated state and in response to an activation of the pulsed current source, the added current being combined with the current from the pulsed current source.

2. The speed-up circuit of claim 1 wherein no current flows to the capacitive load with the pulsed current source deactivated.

3. The speed-up circuit of claim 1 wherein the operational amplifier circuit defines a negative capacitance at a predetermined operating frequency range.

4. The speed-up circuit of claim 1 wherein the operational amplifier circuit includes an operational amplifier with a single ended output, a non-inverting input, and an inverting input.

5. The speed-up circuit of claim 4 wherein the operational amplifier circuit includes a first capacitor connected to the inverting input of the operational amplifier and to a second capacitor connected to the single-ended output of the operational amplifier, and a third capacitor connected to the inverting input and to the first circuit node.

6. The speed-up circuit of claim 5 wherein the operational amplifier circuit includes a first resistor connected to the second capacitor and to the non-inverting input of the operational amplifier, and a second resistor connected to the non-inverting input of the operational amplifier and to ground.

7. The speed-up circuit of claim 6 further comprising a load interconnect resistor connected between the third capacitor and the first circuit node.

8. The speed-up circuit of claim 7 wherein the load interconnect resistor is lower than a resistance of the pulsed current source.

9. An amplifier circuit, comprising:
a primary amplification stage;
a current mirror connected to the primary amplification stage, the current mirror being driven by a pulsed current source; and
a speed-up circuit connected to the current mirror, added current from the speed-up circuit flowing to the current mirror for a predetermined duration between the pulsed current source transitioning between a deactivated state and an activated state and in response to an activation of the pulsed current source, the added current being combined with the current from the pulsed current source to reduce switching time of the current mirror.

10. The amplifier circuit of claim 9 further comprising a mirror resistor connected to the current mirror and to the primary amplification stage.

11. The amplifier circuit of claim 10 wherein the current mirror includes a mirror transistor with a base, a collector connected to the pulsed current source, the speed-up circuit, and the mirror resistor, and an emitter.

12. The amplifier circuit of claim 10 wherein the primary amplification stage includes an amplifier transistor with gate connected to the mirror resistor, a source, and a drain.

13. The amplifier circuit of claim 9 wherein no current from the speed-up circuit flows to the current mirror with the pulsed current source deactivated.

14. The amplifier circuit of claim 9 wherein the speed-up circuit defines a negative capacitance at a predetermined operating frequency range.

15. The amplifier circuit of claim 9 wherein the speed-up circuit includes an operational amplifier with a single ended output, a non-inverting input, and an inverting input.

16. The amplifier circuit of claim 15 wherein the operational amplifier circuit includes a first capacitor connected to the inverting input of the operational amplifier and to a second capacitor connected to the single-ended output of the operational amplifier, and a third capacitor connected to the inverting input.

17. The amplifier circuit of claim 16 wherein the operational amplifier circuit includes a first resistor connected to the second capacitor and to the non-inverting input of the operational amplifier, and a second resistor connected to the non-inverting input of the operational amplifier and to ground.

18. The amplifier circuit of claim 9 wherein the primary amplification stage is radio frequency power amplifier.

19. The amplifier circuit of claim 9 wherein the primary amplification stage is radio frequency low noise amplifier.

20. An amplifier circuit, comprising:
a primary amplification stage;
a current mirror connected to the primary amplification stage, the current mirror being driven by a pulsed current source; and
a speed-up circuit connected to the primary amplification stage, added current from the speed-up circuit flowing to the primary amplification stage for a predetermined duration between the pulsed current source transitioning between a deactivated state and an activated state and in response to an activation of the pulsed current source, the added current being combined with the current from the pulsed current source to reduce switching time of the primary amplification stage.

21. The amplifier circuit of claim 20 wherein the primary amplification stage includes an amplifier transistor with gate connected to the current mirror and to the speed-up circuit, a source, and a drain.

22. The amplifier circuit of claim 20 wherein the current mirror includes a mirror transistor with a base, a collector connected to the pulsed current source and the speed-up circuit, and an emitter.

23. The amplifier circuit of claim 20 wherein no current from the speed-up circuit flows to the current mirror with the pulsed current source deactivated.

24. The amplifier circuit of claim 20 wherein the speed-up circuit defines a negative capacitance at a predetermined operating frequency range.

25. A radio frequency communications module comprising:
a packaging substrate on which a plurality of components are mounted;
an amplifier circuit implemented on the packaging substrate; and
a speed-up circuit implemented on the packaging substrate to reduce charging time of the amplifier circuit from a pulsed current source connected thereto, the speed-up circuit being configured as a low resistance voltage source, with added current from the speed-up circuit flowing to the amplifier circuit for a predetermined duration between the pulsed current source transitioning between a deactivated state and an activated state and in response to an activation of the pulsed current source, the added current being combined with the current from the pulsed current source.

26. The module of claim 25 wherein the amplifier circuit includes a current mirror, the speed-up circuit and the pulsed current source being connected to the current mirror.

27. The module of claim 25 wherein no current from the speed-up circuit flows to the amplifier circuit with the pulsed current source deactivated.

28. The module of claim 25 wherein the speed-up circuit defines a negative capacitance at a predetermined operating frequency range.

29. A wireless communications device comprising:
an antenna receptive to an incoming radio frequency signal and transmissive of an outgoing radio frequency signal;
a radio frequency amplifier circuit connected to the antenna; and
a speed-up circuit to reduce charging time of the radio frequency amplifier circuit from a pulsed current source connected thereto, the speed-up circuit being configured as a low resistance voltage source, with added current from the speed-up circuit flowing to the radio frequency amplifier circuit for a predetermined duration between the pulsed current source transitioning between a deactivated state and an activated state and in response to an activation of the pulsed current source, the added current being combined with the current from the pulsed current source.

30. The wireless communications device of claim 29 wherein the radio frequency amplifier circuit includes a primary amplifier stage with a bias point thereof set by a current mirror.

31. The wireless communications device of claim 29 wherein the speed-up circuit is connected to the current mirror.

32. The wireless communications device of claim 29 wherein the speed-up circuit is connected to the primary amplifier stage.
